(19) United States
(12) Patent Application Publication
(10) Pub. No.: US 2026/0038896 A1
(43) Pub. Date: Feb. 5, 2026

(54) VARIABLE BATTERY ARRANGEMENT, MOTOR VEHICLE AND METHOD FOR OPERATING A BATTERY ARRANGEMENT

(71) Applicant: AUDI AG, lngolstadt (DE)

(72) Inventor: Jakob BÜCH, Bad Friedrichshall (DE)

(73) Assignee: AUDI AG, lngolstadt (DE)

(21) Appl. No.: 19/283,396

(22) Filed: Jul. 29, 2025

(30) Foreign Application Priority Data
Aug. 5, 2024 (DE) 102024122241.7

(51) Int. Cl. H01M 10/48; G01R 31/389; G01R 31/396; H01M 50/509

(52) U.S. Cl. CPC H01M 10/482; G01R 31/389; G01R 31/396; H01M 50/509; H01M 2220/20

(57) ABSTRACT

A battery arrangement with a plurality of cell groups connected in series with one another. Each cell group includes a plurality of battery cells connected in parallel with one another. Each of the battery cells can be selectively connected to and disconnected from one of the cell groups, and the battery arrangement has a measuring device which is designed to determine a specific cell measurement variable for each of the battery cells and to assign the battery cells to exactly one of the cell groups depending on the determined cell measurement variables.

### FIELD

The invention relates to a battery arrangement with a plurality of cell groups connected in series, wherein each cell group comprises a plurality of battery cells connected in parallel. Furthermore, the invention also relates to a motor vehicle having such s battery arrangement and a method for operating a battery arrangement.

### BACKGROUND

The battery arrangement may, for example, be provided in the form of a battery, for example a motor vehicle battery. A battery voltage can be tapped at two tapping points between which the cell groups connected in series are located. The number and voltage level of each individual cell group determine the total voltage that can be tapped at such tapping points. By connecting multiple battery cells in parallel to form a cell group, the overall capacity of the battery can be increased.

By positioning switching elements at a suitable location between battery cells, the battery cells can be connected to each other in a variable manner, for example in series and/or parallel. This can be used for a variety of purposes.

For example, DE 10 2013 113 182 A1 describes an energy storage device for connecting a first voltage network with a first voltage level to at least one second voltage network with a second voltage level, wherein the first voltage level is higher than the second voltage level, and to a plurality of battery cell modules which can be alternately connected to one another in parallel and in series via switching elements. This should allow the implementation of a multi-voltage on-board network.

DE 10 2015 016 980 A1 describes a battery for an on-board electrical system of a motor vehicle, which battery comprises at least two battery strings which can be connected in parallel to one another to a first battery terminal by means of a switching element and which comprises a precharging device which is designed to precharge an intermediate circuit in a first operating mode and to equalize battery voltages of a first battery string and a second battery string in a second operating mode.

DE 10 2016 122 438 A1 describes a dual-voltage battery with a plurality of battery cells, wherein a group of battery cells is respectively connected to form a battery cell block and wherein individual battery cell blocks can be connected in series and/or in parallel and a first voltage is provided by the battery cell blocks in a first connection arrangement and a second voltage is provided in a second connection arrangement.

### SUMMARY

The object of the present invention is to provide a battery arrangement, a motor vehicle and a method which provide at least one further advantageous application possibility for variably interconnectable battery cells.

A battery arrangement according to the invention comprises a plurality of cell groups connected in series, wherein each cell group comprises a plurality of battery cells connected in parallel. Each of the battery cells can be selectively connected to and disconnected from one of the cell groups, wherein the battery arrangement has a measuring device which is designed to determine a specific cell measurement variable for each of the battery cells and to assign the battery cells to exactly one of the cell groups depending on the determined cell measurement variables.

The invention is based on several findings: Battery cells are usually subject to certain tolerances with regard to, for example, internal resistance and/or capacity and/or other cell variables due to manufacturing tolerances or due to varying degrees of aging processes or stress on the battery cell. This can have a negative impact on the overall performance of a conventional battery over time. To give an example, the performance of a conventional battery during operation is limited by the module with the weakest capacity, which can correspond to such a cell group, for example. Typically, such a module with the lowest capacity is the first to reach the final charging or discharging voltage, meaning that the remaining capacities of other modules in a conventional overall battery cannot be fully utilized. In addition, the weakest module is subjected to the greatest load during operation, as the greatest depth of discharge is expected here during cycling. In other words, the discrepancy in the capacities of individual modules or cells of a conventional overall battery will become even greater. Similarly, different internal resistances of cells in a conventional battery lead, for example, to locally varying degrees of heating within the battery and/or to unnecessarily high conduction losses. Now, however, according to the invention, the possibility of being able to selectively switch each of the battery cells of such a battery arrangement on and off from a respective one of several cell groups can be advantageously used to divide the existing battery cells between the cell groups in such a way that, for example, differences in the individual cell measurement variables, viewed in total across the respective cell groups, can be kept to a minimum and, for example, the total capacity of the battery can be maximized, or, for example, the internal resistance of the battery can be minimized overall or another battery variable can be optimized. This can significantly increase the performance of the battery arrangement.

The battery arrangement may, for example, comprise or constitute a battery. Such a battery can in turn have multiple cell groups. For example, the total battery voltage, which essentially corresponds to the sum of the cell group voltages, except for line losses, can be tapped off via battery taps. The series connection of the cell groups can therefore be arranged between the taps. Each cell group in turn comprises multiple battery cells connected in parallel, i.e. at least two. However, the assignment of a battery cell to a cell group is not fixed, but variable. For example, if the battery arrangement comprises a first and a second cell group, a respective battery cell can either be assigned to the first cell group or to the second cell group. A respective battery cell can only ever be part of one of the several cell groups at a time, in particular exactly one of the cell groups. The fact that a battery cell is assigned to one of the cell groups can be understood in particular to mean that the battery cell is then correspondingly part of the parallel circuit comprising the plurality of battery cells encompassed by the cell group. To which of the multiple cell groups a respective battery cell is assigned can in turn be determined by the measuring device on the basis of the detected cell measurement variables.

In the present case, the battery cells can be lithium-ion cells, for example. These can basically be designed as prismatic battery cells, pouch cells or round cells. The battery arrangement can in particular be a high-voltage battery, in particular for a motor vehicle.

For selectively connecting and disconnecting a respective battery cell to a cell group or from a cell group, the battery arrangement may also comprise corresponding switching elements, in particular switches, for example electronically controllable switches or semiconductor switches.

According to an advantageous embodiment, the measuring device is designed to connect the battery cells to the respective assigned cell groups depending on the determined cell measurement variables, after assignment to the respective cell group, if the battery cell in question has not yet been connected to the assigned cell group. In other words, a battery cell does not necessarily have to be switched from one cell group to another depending on the determined cell measurement variables if the battery cell in question is already connected to the cell group that is assigned to it by the measuring device on the basis of the cell measurement variables.

The assignment of battery cells to cell groups can, for example, be carried out with the objective of optimizing, for example maximizing or minimizing, a specific measurement variable which can be determined depending on the specific cell measurement variables. If it is possible while complying with the objective, the measuring device can also be designed to carry out the switching of the battery cells to the assigned cell groups in such a way that, as a secondary condition, the number of required switching operations can be minimized. This advantageously avoids unnecessary switching operations.

According to a further advantageous embodiment of the invention, each of the cell groups comprises an equal number of battery cells and/or a number of cell groups connected in series is fixed. For example, it can be provided that switching the battery cells or assigning them to the respective cell groups does not change the number of battery cells assigned to a single cell group or the number of cell groups connected in series. In other words, assigning the battery cells to the cell groups should not change the overall voltage of the battery, and ideally no battery cell should remain unused, although this would still be conceivable. It is also very advantageous if each cell group contains the same number of battery cells, as this makes it easier to minimize the difference, for example, between the capacities of the cell groups as a whole.

According to a further advantageous embodiment of the invention, the cell measurement variable represents a capacitance. It is therefore very advantageous if the measuring device uses the capacities detected for each battery cell to assign the battery cells to the cell groups in such a way that the overall capacity of the battery can be maximized. Even if there are differences in the capacities of the battery cells, which may arise due to manufacturing or aging, in particular due to slightly different aging and/or load of the battery cells over time, the effects on the total capacity of the battery cell can thus be minimized and the maximum possible total capacity for the battery can always be provided.

Accordingly, it represents a further very advantageous embodiment of the invention if the measuring device is designed to assign the battery cells to the cell groups and to connect them thereto as a function of the determined capacities of the respective battery cells in such a way that a minimum cell group capacity of all cell group capacities, which is calculated for a respective one of the cell groups as a sum of the capacities of the battery cells assigned to the cell group, is maximum. If a single cell group comprises multiple battery cells with a respective capacity, the cell group capacity, i.e. the total capacity of the entire cell group, is the sum of the individual capacities of the battery cells assigned to the cell group. Since the individual cell groups are connected in series, the total capacity of the entire battery or this entire series connection results as the minimum cell group capacity. In order to maximize the total capacity of the entire series circuit, the battery cells can advantageously be assigned in such a way that the minimum cell group capacity is maximized. In other words, the standard deviation or dispersion or variance of the cell group capacities is minimized around the mean capacity value. In the simplest case, the measuring arrangement can, for example, determine, for all finitely possible configurations of the assignment of battery cells to cell groups, which minimum cell group capacity occurs for each of the possible cell grouping configurations and then select the configuration which has the largest minimum cell group capacity. However, numerous other calculation options are conceivable to determine the configuration with the maximum minimum cell group capacity. In particular, it is conceivable that several different configurations can lead to such a maximum minimum cell group capacity. Then, for example, one of these “most efficient” configurations can be selected according to other criteria or one of the most efficient configurations can be selected at random.

This advantageous possibility of maximizing the total capacity of the battery arrangement not only makes it possible to provide the maximum possible capacity for the battery arrangement, but also allows different degrees of aging of the cell groups to be avoided or significantly reduced, which is made possible by the more even loading of the cell groups through the adapted assignment of the battery cells to the respective cell groups.

Furthermore, it is advantageous if the connection and/or disconnection or switching of battery cells between the cell groups only takes place when the battery arrangement is not under load, e.g. when no current flows through the battery arrangement, neither a load current nor a charging current.

According to a further advantageous embodiment of the invention, the cell measurement variable represents an inner resistance. This advantageously also makes it possible to optimize the internal resistance. This can be used, for example, to homogenize temperature distribution within the battery arrangement and/or to minimize power loss.

Accordingly, it represents a further advantageous embodiment of the invention if the measuring device is designed to assign the battery cells to the cell groups depending on the determined internal resistances of the respective battery cells, and in particular to connect them, so that a total resistance of the cell groups connected in series is minimal and/or a sum of the deviations of the internal resistances from an internal resistance mean value for each cell group and/or for the cell groups as a whole is minimal. Instead of the sum of the deviations, for example, the sum of a square of the deviation and/or a root of the sum of the square of the deviation can be considered as the quantity to be minimized. This makes it possible, for example, to homogenize the internal resistance distribution, which enables particularly homogeneous heating of the battery arrangement. Additionally or alternatively, the assignment of cells to cell groups can also be carried out with the objective of minimizing the total internal resistance of the cell groups connected in series. This in turn reduces the power loss of the battery arrangement during operation.

With regard to these optimizations, it may also happen that not only one configuration is optimal, but that there are several possible optimal configurations. Then one of these optimal configurations can be selected again randomly or according to another criterion.

According to a further advantageous embodiment of the invention, the measuring arrangement is designed to repeatedly determine the specific cell measurement variable for each of the battery cells and to assign the battery cells to one of the cell groups depending on the determined cell measurement variables and in particular to connect them to this group. The determination of the cell measurement variables and the assignment of the battery cells to the cell groups based on this can therefore advantageously be carried out repeatedly over time. This allows for optimal adaptation over time and the performance of the battery arrangement to be maintained at a high level over the long term.

Furthermore, the invention also relates to a motor vehicle having a battery arrangement according to the invention or one of its embodiments.

The invention further relates to a method for connecting a battery arrangement with a plurality of cell groups connected in series, wherein each cell group comprises a plurality of battery cells connected in parallel. Each of the battery cells can be selectively connected to and disconnected from one of the cell groups, wherein the battery arrangement has a measuring device which determines a specific cell measurement variable for each of the battery cells and assigns the battery cells to exactly one of the cell groups depending on the determined cell measurement variables.

The advantages mentioned for the battery arrangement according to the invention and its embodiments thus apply similarly to the method according to the invention.

The invention also includes developments of the method according to the invention, which have features as have already been described in conjunction with the developments of the battery arrangement according to the invention. For this reason, the corresponding developments of the method according to the invention are not described again here.

For applications or usage situations that can arise in the method and which are not explicitly described here, it can be provided according to the method, that a fault message and/or a request for input of user feedback is output and/or a standard setting and/or a predetermined initial status are set.

The measuring device for the motor vehicle is also part of the invention. The measuring device can have a data processing device or a processor device (processor circuit) which is configured to carry out an embodiment of the method according to the invention. For this purpose, the processor device can have at least one microprocessor and/or at least one microcontroller and/or at least one FPGA (Field Programmable Gate Array) and/or at least one DSP (Digital Signal Processor). In particular, a CPU (Central Processing Unit), a GPU (Graphical Processing Unit) or an NPU (Neural Processing Unit) can be used as a microprocessor. Furthermore, the processor device can have program code which is configured to carry out the embodiment of the method according to the invention when it is executed by the processor device. The program code can be stored in a data memory of the processor device. The processor device can be based, for example, on at least one circuit board and/or at least one SoC (System on Chip).

The motor vehicle according to the invention is preferably designed as an automobile, in particular as a passenger car or truck, or as a passenger bus or motorcycle.

The invention also comprises the combinations of the features of the described embodiments. The invention therefore also comprises implementations which each have a combination of the features of several of the described embodiments, unless the embodiments have been described as mutually exclusive.

### BRIEF DESCRIPTION OF THE FIGURES

Exemplary embodiments of the invention are described hereinafter. In the figures:

FIG. 1 shows a battery according to an example not belonging to the invention; and

FIG. 2 shows a schematic illustration of a battery arrangement according to an exemplary embodiment of the invention.

### DETAILED DESCRIPTION

The exemplary embodiments explained below are preferred embodiments of the invention. In the exemplary embodiments, the described components of the embodiments each represent individual features of the invention to be considered independently of one another, which each also develop the invention independently of one another. Therefore, the disclosure is also predetermined to comprise combinations of the features of the embodiments other than those represented. Furthermore, the described embodiments can also be supplemented by further ones of the above-described features of the invention.

In the figures, same reference numerals respectively designate elements that have the same function.

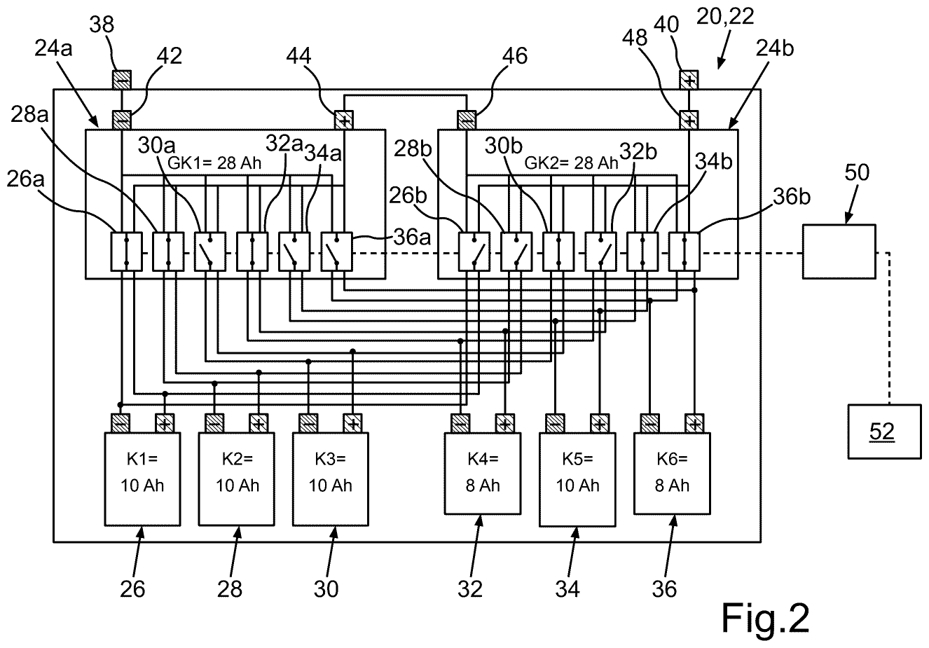

Fig. shows a schematic representation of a battery 10 according to an example not belonging to the invention. The battery 10 comprises, by way of example, two battery modules 12a, 12b. The two battery modules 12a, 12b are connected in series. Each of the battery modules 12a, 12b comprises, by way of example, three battery cells 14a, 16a, 18a and 14b, 16b, 18b. The battery cells 14a, 16a, 18a and 14b, 16b, 18b within a same module 12a or 12b are connected in parallel to each other. The battery cells 14a, 16a, 18a of the first battery module 12a each have a capacity of, for example, 10 ampere hours, resulting in a module capacity of the first battery module 12a of 30 ampere hours. The cells 14b and 18b of the second module 12b each have a cell capacity of 8 ampere hours, and the battery cell 16b has a capacity of 10 ampere hours. This results in a total module capacity of the second module 12b of 26 ampere hours. According to such a configuration, the module 12b with the capacity of 26 ampere hours is most heavily loaded during the operation of the battery 10, and the capacity of 30 ampere hours of the first module 12a is not fully utilized during operation. This can now advantageously be prevented by the invention or its embodiments, as will now be described in more detail below by means of FIG. 2.

FIG. 2 shows a schematic illustration of a battery arrangement 20 according to an exemplary embodiment of the invention. The battery arrangement 20 can represent a battery 22, for example a high-voltage battery. In the following example, the battery arrangement 20 exemplarily comprises two cell groups 24a, 24b and a total of six battery cells 26, 28, 30, 32, 34, 36. The first battery cell 26 has a capacity K1 of 10 ampere hours, the second battery cell 28 has a second capacity K2 of 10 ampere hours, the third battery cell 30 has a capacity K3 of 10 ampere hours, the fourth battery cell 32 has a capacity K4 of 8 ampere hours, the fifth battery cell 34 has a capacity K5 of 10 ampere hours and the sixth battery cell 36 has a capacity K6 of 8 ampere hours.

In addition, the battery arrangement 20 comprises two main taps 38, 40. The tap 38 corresponds to a negative pole of the battery and the tap 40 to a positive pole of the battery. The two cell groups 24a, 24b also each have two taps 42, 44, 46, 48, wherein here again the taps 42 and 48 correspond to a negative pole of the respective cell groups 24a and 24b, respectively, and the taps 44 and 48 to respective positive poles. Each of the battery cells 26, 28, 30, 32, 34, 36 also has a positive pole and a negative pole, which are, however, only symbolized by the symbols “minus” and “plus”.

Each of the battery cells 26, 28, 30, 32, 34, 36 is assigned two switching units 26a, 26b, 28a, 28b, 30a, 30b, 32a, 32b, 34a, 34b, 36a and 36b, which in turn can be subdivided into first and second switching units. In particular, the first switching units 26a, 28a, 30a, 32a, 34a, 36a can be assigned to the first cell group 24a and the second switching units 26b, 28b, 30b, 32b, 34b, 36b can be assigned to the second cell group 34b. The assignment may consist in the fact that, when the switching unit in question is closed, the battery cell assigned to this switching unit is connected to the assigned cell group. Using the example of the first battery cell 26, the first switching unit 26a and the second switching unit 26b are assigned to this battery cell 26. If the first switching unit 26a is closed, the battery cell 26 is assigned to the first cell group 24a and connected thereto, and if, on the other hand, the second switching unit 26b is closed, the first cell 26 is assigned to the second cell group 24b and connected thereto. Each one of the two switching units assigned to each battery cell is therefore in a closed state, the other in an open state or vice versa. Thus, each cell is assigned to or connected to exactly one of the two cell groups 24a, 24b. The switching units can be controlled by a control device 50 of the battery arrangement 20. This can also be called a battery management controller (BMC). The control device 50 may also comprise a measuring device 52 or be coupled to such a measuring device 52.

The measuring device 52 can, for example, detect the individual capacities K1, K2, K3, K4, K5, K6 of the cells and the control device 50 can then control the switching units in such a way that, for example, the minimum cell group capacity can be maximized. According to the switching configuration of the individual switching elements shown here, the first cell group 24a has a cell group capacity GK1 of 28 ampere hours and the second cell group 24b has a cell group capacity GK2 of also 28 ampere hours.

According to this configuration, the first cell 26, the second cell 28 and the fourth cell 32 are, for example, part of the first cell group 24a and, accordingly, the remaining cells 30, 34, 36 are part of the second cell group 24b. In this example, there would be further configurations that would result in a respective cell group capacity GK1, GK2 of 28 ampere hours. So other configurations are conceivable. In other words, there may be not just one ideal configuration, but several that are equally advantageous with regard to the same variable to be optimized, such as capacity in this case. Then, one of the several possible configurations can be selected randomly or according to a predetermined criterion, for example with regard to the optimization of another variable, for example the minimization of a respective internal resistance or the total internal resistance of the battery, the reduction of switching operations or the like.

In the same way, an optimization of a certain variable can also be achieved if more than two cell groups 24a, 24b are provided.

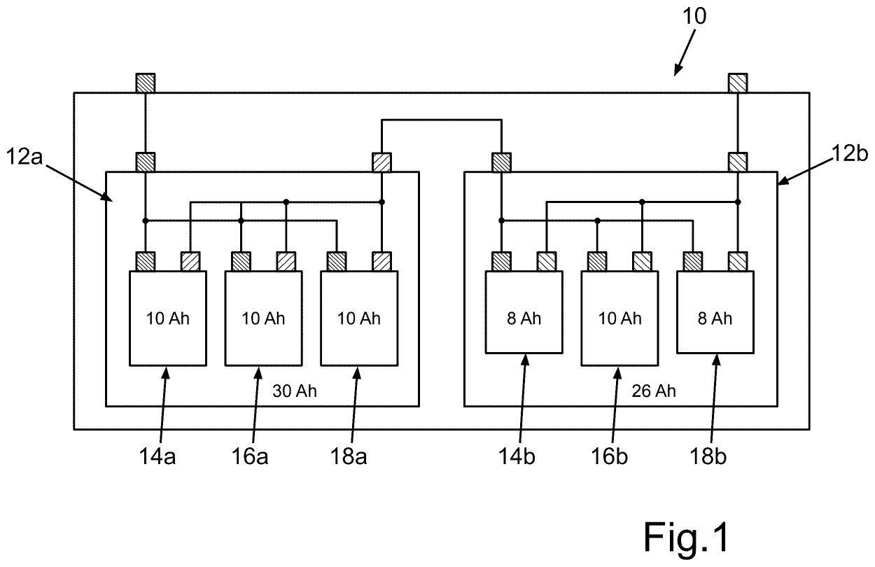

In this example, the variable arrangement advantageously allows the lowest capacity in the system, particularly in cell groups 24a, 24b, to be optimized. In this example, it is therefore 28 ampere hours, while according to the example in FIG. 1, which includes cells with the same individual capacities, it is only 26 ampere hours. According to the present example, the variable arrangement allows 2 more ampere hours to be used. It is also conceivable to optimize not only the capacity as a measurement variable, but also other variables, such as the energy content of the battery, the balancing requirement, the internal resistance or similar.

Overall, the examples show how the invention can provide a variable cell arrangement in batteries or battery modules to optimize characteristic parameters of the overall battery, for example capacity, internal resistance, energy. The assignment of cells to modules is not rigidly connected, but each cell can be selectively connected to a module of the battery via a connecting or separating element, e.g. switch. A control device, which can also be called a battery module controller, which contains characteristic variables about each cell, calculates an arrangement of the cells that corresponds to an optimal assignment of the cells to modules and controls the connecting and/or separating elements accordingly. By optimally assigning the cells to modules, weak cells can be connected in parallel with strong cells, so that the overall battery has an optimum capacity, energy content or balancing requirement. This means that the modules can be loaded more symmetrically and the cells can be used more effectively.

The characteristic variables for each cell can be detected in the battery management control unit. Using an algorithm, for example using a squared deviation calculation or similar, an assignment of cells to modules can be calculated which results in the smallest deviation among the serially connected modules. If it is determined that the current assignment is no longer optimal, the connecting and/or separating elements are controlled with the new optimal configuration in the load-free state. A load-free state of the battery arrangement exists in particular when the main contactors of the battery are open. The control device can also ensure that each cell is assigned to only one module. If necessary, individual cells can be partially discharged before rewiring so that no critical equalizing currents occur when connecting to modules.

1. A battery arrangement, comprising:
a plurality of cell groups connected in series with one another, wherein each cell group comprises a plurality of battery cells connected in parallel with one another,
wherein each of the battery cells can be selectively connected to and disconnected from one of the cell groups, and
wherein the battery arrangement has a measuring device which is designed to determine a specific cell measurement variable for each of the battery cells and to assign the battery cells to exactly one of the cell groups depending on the determined cell measurement variables.

2. The battery arrangement according to claim 1, wherein the measuring device is designed to connect the battery cells to the respectively assigned cell group as a function of the determined cell measurement variables, after assignment to the respective cell group, if the relevant battery cell of the assigned cell group has not yet been connected.

3. The battery arrangement according to claim 1, wherein each of the cell groups comprises an equal number of battery cells and/or a number of cell groups connected in series is fixed.

4. The battery arrangement according to claim 1, wherein the cell measurement variable represents a capacity.

5. The battery arrangement according to claim 1, wherein the measuring device is designed to assign the battery cells to the cell groups and to connect them thereto as a function of the determined capacities of the respective battery cells in such a way that a minimum cell group capacity of all cell group capacities, which is calculated for a respective one of the cell groups as a sum of the capacities of the battery cells assigned to the cell group, is maximum.

6. The battery arrangement according to claim 1, wherein the cell measurement variable represents an internal resistance.

7. The battery arrangement according to claim 1, wherein the measuring device is designed to assign the battery cells to the cell groups and to connect them thereto as a function of the determined internal resistances of the respective battery cells in such a way that a total resistance of the series-connected cell groups is minimal and/or a sum of the deviations of the internal resistances from an internal resistance mean value for each cell group and/or for the cell groups as a whole is minimal.

8. The battery arrangement according to claim 1, wherein the battery arrangement is designed such that for each of the battery cells, the determined cell measurement variable is repeatedly determined and the battery cells are assigned and connected to a respective one of the cell groups depending on the determined cell measurement variables.

9. A motor vehicle having a battery arrangement according to claim 1.

10. A method for connecting a battery arrangement with a plurality of cell groups connected in series with one another, wherein each cell group comprises a plurality of battery cells connected in parallel with one another,
wherein each of the battery cells can be selectively connected to and disconnected from one of the cell groups, and
wherein the battery arrangement has a measuring device which is designed to determine a specific cell measurement variable for each of the battery cells and to assign the battery cells to exactly one of the cell groups depending on the determined cell measurement variables.

11. The battery arrangement according to claim 2, wherein each of the cell groups comprises an equal number of battery cells and/or a number of cell groups connected in series is fixed.

12. The battery arrangement according to claim 2, wherein the cell measurement variable represents a capacity.

13. The battery arrangement according to claim 3, wherein the cell measurement variable represents a capacity.

14. The battery arrangement according to claim 2, wherein the measuring device is designed to assign the battery cells to the cell groups and to connect them thereto as a function of the determined capacities of the respective battery cells in such a way that a minimum cell group capacity of all cell group capacities, which is calculated for a respective one of the cell groups as a sum of the capacities of the battery cells assigned to the cell group, is maximum.

15. The battery arrangement according to claim 3, wherein the measuring device is designed to assign the battery cells to the cell groups and to connect them thereto as a function of the determined capacities of the respective battery cells in such a way that a minimum cell group capacity of all cell group capacities, which is calculated for a respective one of the cell groups as a sum of the capacities of the battery cells assigned to the cell group, is maximum.

16. The battery arrangement according to claim 4, wherein the measuring device is designed to assign the battery cells to the cell groups and to connect them thereto as a function of the determined capacities of the respective battery cells in such a way that a minimum cell group capacity of all cell group capacities, which is calculated for a respective one of the cell groups as a sum of the capacities of the battery cells assigned to the cell group, is maximum.

17. The battery arrangement according to claim 2, wherein the cell measurement variable represents an internal resistance.

18. The battery arrangement according to claim 3, wherein the cell measurement variable represents an internal resistance.

19. The battery arrangement according to claim 4, wherein the cell measurement variable represents an internal resistance.

20. The battery arrangement according to claim 5, wherein the cell measurement variable represents an internal resistance.
